(19) United States
(12) Patent Application Publication
(10) Pub. No.: US 2005/0161779 A1
(43) Pub. Date: Jul. 28, 2005

(54) Flip chip assemblies and lamps of high power GaN LEDs, wafer level flip chip package process, and method of fabricating the same

(76) Inventors: Hui Peng, Fremont, CA (US); Gang Grant Peng, Fremont, CA (US)

Correspondence Address: Hui Peng, 35964 Vivian Place, Fremont, CA, 94536, US

(21) Appl. No.: 10/765,346

(22) Filed: Jan. 26, 2004

(51) Int. Cl. H01L 21/44; H01L 23/02; H01L 29/40

(52) U.S. Cl. 257/678; 438/106; 438/108; 257/778

(57) ABSTRACT

The present invention discloses new flip chip assemblies and lamps for high power semiconductor chips or devices including GaN LEDs and a new wafer level flip chip packaging process for cost effectively manufacturing the same. The advantages of the new flip chip assemblies, lamps, and the wafer level flip chip package process are: (1) the fabricating process is simpler; (2) no need for expensive flip chip equipments; (3) the throughput is higher; (4) eliminating lattice mismatch between the substrate and the epitaxial layer by removing the substrate; (5) better thermal dissipation; (6) reduced current crowding effect and higher current density; (7) higher light extraction efficiency; (8) eliminating the totally internal reflection; and (9) eliminating the Fresnel reflection at the dome-air interface.

### BACKGROUND OF THE INVENTION

(1) Field of the Invention

The present invention relates to new flip chip assemblies and lamps of high power semiconductor chips or devices including high power GaN LEDs and a new wafer level flip chip package process for fabricating the same.

(2) Prior Art

The chip level flip chip package process, especially for high power GaN LEDs, has following issues: (1) the process is complicate, packaging equipments are expensive, and the throughput is low, which are the bottlenecks for the fabrication of flip chip assemblies of high power GaN LEDs; (2) the limited thermal dissipation due to the usage of organic underfill materials; (3) the lattice mismatch still existing for GaN LEDs with a sapphire substrate; and (4) the totally internal reflection causing low extraction efficiency.

The chip level flip chip package process of prior art comprises the following steps: disposing bumps with accurate position, size, and height onto a submount wafer, dicing the submount wafer into individual submount chips, flip-chip placing each individual semiconductor chip on each submount chips accurately, and under filling the gap between the semiconductor chip and the submount chip with epoxy. Even without the underfilling, the chip level flip chip package process is still complex.

Thermal dissipation is a critical issue for assemblies of high power semiconductor chips or devices including high power GaN LEDs, which determines the overall performance and quality of semiconductor chip assemblies. The limited thermal dissipation will show its limitation when the device power migrants to higher level.

The lattice mismatch between the substrate and the epitaxial layer still exists after the flip chip process of the prior art. For GaN LEDs with GaN substrate, there is no longer the lattice mismatch, however, the GaN substrate is much expensive than sapphire substrate, and GaN substrate absorbs the emitted light.

The totally internal reflection significantly reduces the external efficiency. For GaN LEDS, the refractive index of GaN, sapphire substrate, and epoxy dome are respectively about 2.5, 1.8, and 1.5. The emitted light is trapped in each of the following cases, when the angle of the light incidence at the GaN-sapphire interface, at the sapphire-epoxy interface, and at the epoxy-air interface is less than the critical angle determined by Snell's law. For GaN LEDs with GaN substrate, there are still the totally internal reflections at the GaN substrate-epoxy interface and at the epoxy-air interface There are varieties of prior art discussing flip chip technology for semiconductor chips, including U.S. Pat. No. 6,483,196 B1 by Wojnarowski et al. for flip chip, U.S. Pat. No. 6,455,878 B1 by Bhat et al. for flip chip LEDs having low refractive index under fill, U.S. Pat. No. 6,517,218 B2 by Hochstein et al. for heat sink, U.S. Pat. No. 6,649,440 by Krames, et al. for a thick multi-epitaxial-layers LEDs for increasing the light extraction efficiency by allowing emitted light escaping the LED through the sides of the thick epitaxial layers, and U.S. Pat. No. 6,646,292 by Steigerwald et al for dicing first and then attaching chip to submount process with high index substrate.

There are increasing demands for new flip chip assemblies, new lamps, and a wafer level flip chip package process for cost effectively producing assemblies and lamps of high power semiconductor chips or devices with higher throughput.

### BRIEF SUMMARY OF THE INVENTION

In the present invention, new assemblies, new lamps, and a new wafer level flip chip package process for high power semiconductor chips or devices are disclosed. GaN LEDs are used as preferred embodiments of the present invention. However, the new assemblies, lamps, and wafer lever flip chip package process of the present invention are also applicable to other semiconductor chips or devices.

The wafer level flip chip package process of the present invention for GaN LEDs comprises the following process steps. Firstly, bonding an epitaxial wafer epitaxial-side down to a submount wafer to form a bonded LED wafer. Secondly, removing the sapphire or GaN substrate of the bonded LED wafer. Thirdly disposing a patterned electrical contact pad to the epitaxial layer that previously contacted to the removed substrate. Finally dicing the bonded LED wafer into individual discrete chips.

The present invention has the following advantages.
1. Since the new flip chip package process of the present invention is a wafer level flip chip package process and there is no chip level flip chip package process involved, therefore: (1) the throughput is very high; (2) the process is much simpler; (3) there are no expensive flip chip equipments needed.
2. Since the substrate has been removed, the effects of lattice mismatch between a sapphire substrate and the epitaxial layer is no longer existing, thus, the internal efficiency of the GaN LEDs with sapphire substrate is improved.
3. The one side of the epitaxial layer of a semiconductor chip metallically contacts to a submount chip, which results in an excellent thermal path to dissipate the heat generated by the semiconductor chip including a GaN LED with either sapphire or GaN substrate.
4. The other side of the epitaxial layer of the semiconductor chip, after removing the substrate, is directly exposed to a dome material that has the same refractive index as that of the epitaxial layer, which results in eliminating totally internal reflection when light incidents from the epitaxial layer to the dome.
5. The shape, diameter, and added materials of the dome is so determined that there is no totally internal reflection when light incidents from the dome to air. Therefore there is no trapped light for the new lamps of the present invention.
6. By coating an anti-reflection optical layer on the surface of the dome, there is no Fresnel reflection at the dome-air interface.
7. The flip chip assemblies and the wafer level flip chip package process of the present invention have all of the advantages of flip chip technique without its disadvantage.
8. For GaN LEDs, the sapphire substrate has been removed, so the cost of the dicing process is much lower.
9. Both electric contact pads are on the different sides of a GaN LED chip, the top contact pad may be so patterned and arranged that to reduce the current crowding effect, to fully utilize the material of active layer, and to distribute the current more evenly.
10. The current density may be higher, thus the GaN LEDs are brighter.

The primary object of the present invention is to provide new flip chip assemblies and lamps for high power semiconductor chips or devices including GaN LEDs to have fast thermal dissipation, higher light extraction, and reduced current crowding effect.

The second object of the present invention is to provide a new wafer level flip chip package process for cost effectively manufacturing the flip chip assemblies of high power semiconductor chips or devices including GaN LEDs with high throughput.

The third object of the present invention is to provide new flip chip assemblies and lamps of semiconductor chips or devices to significantly improve the extraction efficiency by eliminating both the totally internal reflection and the Fresnel reflection at the dome-air interface.

The fourth object of the present invention is to provide new flip chip assemblies of semiconductor chips or devices to eliminate the lattice mismatch to improve the internal efficiency.

Further objects and advantages of the present invention will become apparent from a consideration of the ensuing description and drawings.

### BRIEF DESCRIPTION OF THE SEVERAL VIEWS OF DRAWINGS

The novel features believed characteristic of the present invention are set forth in the claims. The invention itself, as well as other features and advantages thereof will be best understood by referring to detailed descriptions that follow, when read in conjunction with the accompanying drawings.

FIG. 1a is a cross sectional view of a flip chip assembly of a semiconductor chip bonded on a submount chip of prior art.

FIG. 1b is a cross sectional view of a lamp of the flip chip assembly of prior art.

FIG. 2a to 2e show a preferred embodiment of the wafer lever flip chip package process of the present invention.

FIG. 2a is the flow chart of the wafer lever flip chip package process.

FIG. 2b is a cross sectional view of both a submount wafer and an epitaxial wafer with a substrate.

FIG. 2c is a cross sectional view of a bonded LED wafer formed by bonding the epitaxial wafer epitaxial side down to the submount wafer.

FIG. 2d is a cross sectional view of the bonded LED wafer of FIG. 2c with the substrate of the epitaxial wafer removed.

FIG. 2e is a cross sectional view of patterned top contact pads disposed on the epitaxial layer of the bonded LED wafer of FIG. 2d.

FIG. 3a to 3j show embodiments of different patterns of the top contact pads of the present invention comprising contact pads and wire bonding pads.

FIG. 3a is a top view of a grid-ring-shaped top contact pad with one wire bonding pad at a corner of the top contact pad.

FIG. 3b is a cross sectional view of the top contact pad of FIG. 3a.

FIG. 3c is a top view of a grid-ring-shaped top contact pad with multiple wire bonding pads.

FIG. 3d is a top view of a ring-shaped top contact pad with current spreading layer and one wire bonding pad at a corner.

FIG. 3e is a top view of a ring-shaped top contact pad with current spreading layer and multiple wire bonding pads.

FIG. 3f is a top view of a plus-ring-shaped top contact pad.

FIG. 3g is a top view of a plus-ring-shaped top contact pad with current spreading layer and multiple wire bonding pads.

FIG. 3h is a top view of a plus-multiple-ring-shaped top contact pad.

FIG. 3i is a top view of a plus-multiple-ring-partition-shaped top contact pad with partitions in between two rings.

FIG. 3j is a top view of a grid-ring-shaped top contact pad with a strip-shaped wire bonding pad.

FIG. 4a is a cross sectional view of a lamp of a flip chip assembly comprising LED chip assembly, hemisphere-shaped material or dome, anti-reflection coating on the surface of the hemisphere-shaped material, and reflective cup.

FIG. 4b is a cross sectional view of a lamp of a flip chip assembly comprising LED chip assembly, hemisphere-shaped material, anti-reflection coating on the surface of the hemisphere-shaped material, neck, and reflective cup.

FIG. 4c is a drawing for calculating the minimum diameter of the hemisphere-shaped material.

### DETAILED DESCRIPTION OF THE INVENTION

While embodiments of the present invention will be described below, those skilled in the art will recognize that other assemblies, lamps and processes are capable of implementing the principles of the present invention. Thus the following description is illustrative only and not limiting.

Reference is specifically made to the drawings wherein like numbers are used to designate like members throughout.

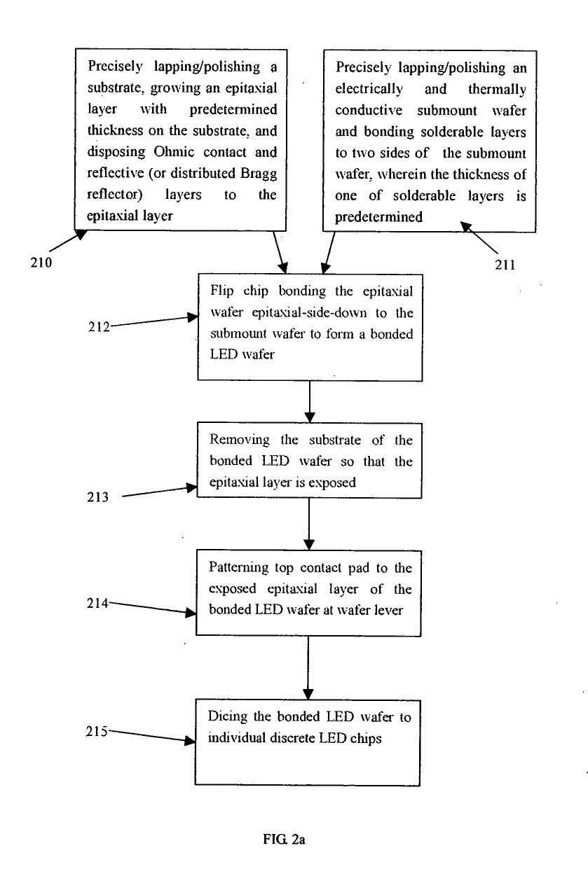

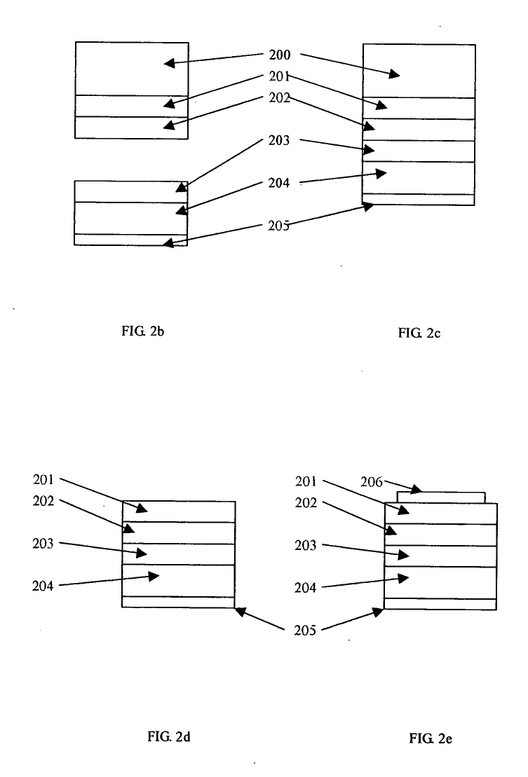

Note the followings:
(1) The dimensions of all of drawings are not to scale.
(2) GaN LEDs as embodiments of the present invention are illustrated in the FIG. 2 to FIG. 4. However the same flip chip assemblies and package process are applicable to other semiconductor chips or devices.
(3) Although a sapphire substrate has been used in FIG. 2 to FIG. 4, for GaN LEDs, the substrate may be GaN. Also Si wafer has been tried for growing GaN LEDs. The flip chip package process of the present invention is applicable for GaN LEDs with Si substrate. Actually flip chip assemblies are substrate-independence.
(4) There is either with or without a current spreading layer (window) on all of semiconductor chips or devices of the present invention.
(5) There is at least one wire bonding pad contacted to the same confinement layer for all of flip chip assemblies of semiconductor chips or devices of the present invention.
(6) The thickness of the first solderable layer of the submount wafer is predetermined to compensate the roughness of the surface of the epitaxial layer when bonding the first solderable layer to the epitaxial layer.

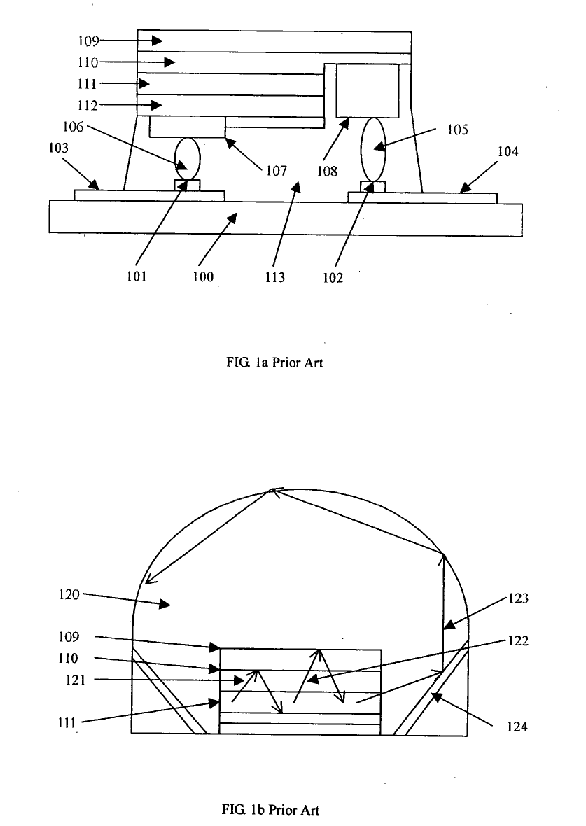

FIG. 1a is a cross sectional view of a prior art flip chip assembly of a semiconductor device or chip. The semiconductor chip is bonded epitaxial side down to submount 100. Active layer 111 is sandwiched between P confinement layer 112 and N confinement layer 110 that is disposed on substrate 109.

For GaN LEDs, the emitting light will be reflected back to pass through the transparent sapphire substrate 109. Bump 105 and 106 respectively bond N and P contact pad 108 and 107 to bonding pad 102 and 101 of submount 100. Wire bonding pad 103 and 104 contact bonding pad 101 and 102 respectively.

However most area of the top surface of the GaN LED chip contacts underfill epoxy 113 that does not have good thermal conductance. Therefore overall thermal dissipation is lower.

Note that substrate 109 may be GaN substrate which has absorption.

FIG. 1b is a cross sectional view of a lamp. The lamp comprises the flip chip assembly of FIG. 1a, reflective cup 124, and dome 120. Dome 120 may be made of either epoxy or other transparent materials. The significant portion of the light emitted by active layer 111 is totally internally reflected. Light 121, 122, and 123 are totally internally reflected at the epitaxial layer-substrate, substrate-dome, and dome-air interfaces respectively. Encapsulating reflective cup 124 by dome 120 causes the totally internal reflection of light 123.

For GaN LEDs with GaN substrate, there are only the totally internal reflections at the GaN substrate-dome and the dome-air interfaces.

FIG. 2a to 2e show an embodiment of the wafer level flip chip package process of the present invention.

FIG. 2a is a flow chart of the wafer level flip chip package process of the present invention. Step 210/211, 212, 213, and 214 respectively correspond to FIG. 2b, 2c, 2d, and 2e. Step 215 is dicing the bonded LED wafer into individual dies.

FIG. 2b shows preparations of both a GaN epitaxial wafer and submount wafer 204. Epitaxial layer 201 disposes on sapphire substrate 200. Reflective and Ohmic contact layer 202 are disposed on epitaxial layer 201. First and second solderable layer 203 and 205 are disposed on two sides of submount wafer 204 respectively.

Substrate 200 may be GaN, Si, or others.

The material of reflective layer may be selected from a group comprising Al, Au, and Ag.

Note that the reflective layer may be the distributed Bragg reflector.

Submount wafer 204 has good thermal and electrical conductance and is selected from a group of materials comprising SiC, Cu, CuW, and Al.

For successfully removing the substrate after bonding a submount wafer to an epitaxial wafer as illustrated in FIG. 2, the followings need to be emphasized:
a. The substrate wafer is precisely lapped/polished so that the total thickness variation is minimized;
b. The thickness of the epitaxial layer grown on the substrate wafer is uniform over whole wafer;
c. The submount wafer is precisely lapped/polished so that the total thickness variation is minimized;
d. The thickness of the epitaxial layer grown on the substrate wafer is predetermined to compensate the total thickness variations of the substrate and submount wafers;
e. The thickness of the solderable layers is uniform;
f. When pressingly bonding the epitaxial wafer and the submount wafer, bond the thicker portion of one wafer to the thinner portion of other wafer.

In FIG. 2c, the GaN epitaxial wafer is pressingly bonded epitaxial-side-down to submount wafer 204, i.e., reflective and Ohmic contact layer 202 is bonded to first solderable layer 203 of submount wafer 204, to form a bonded LED wafer.

This process step is simple, inexpensive, and the key step of an embodiment of the wafer lever flip chip process of the present invention.

FIG. 2d shows that the sapphire substrate is, then, removed by lapping/polishing.

For GaN LEDs with GaN substrate, the GaN substrate may also be removed by plasma etching process.

Also the GaN substrate of GaN LEDs may not be removed although GaN substrate absorbing emitted light.

After the removal of the sapphire substrate, the epitaxial layer is exposed.

Then, as shown in FIG. 2e, patterned Ohmic contact pad 206 is disposed on the top of epitaxial layer 201.

For GaN LEDs, patterned Ohmic contact pad 206 is N contact pad. P contact pad is electrically connected with second solderable layer 205 through submount wafer 204.

Up to now, all of fabrication steps are processed at wafer level.

Finally, the bonded LED wafer comprising submount wafer 204, epitaxial layer 201 and without substrate is diced into individual discrete chips.

As shown in FIG. 2, (1) all of process steps except dicing are done at wafer level and, thus, throughput is much higher; (2) there is no need for disposing bumps; (3) there is no chip level flip chip package process; (4) there is no need for underfill; (4) there is no need for etching down to N confinement layer to dispose N contact pad on the same side of a LED wafer as P contact pad; (5) there is no longer the effect of the lattice mismatch between epitaxial layer and sapphire substrate; (6) the reflective layer covers the whole submount chip.

Therefore new flip chip assemblies and wafer level flip chip package process have all of advantages of flip chip assembly without the disadvantages, the performance of the LED chips is much better, and the cost of fabrication is much lower.

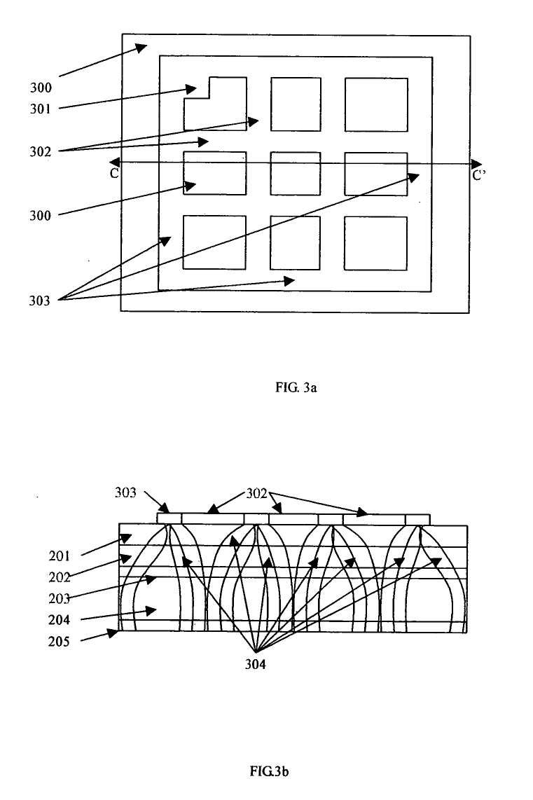

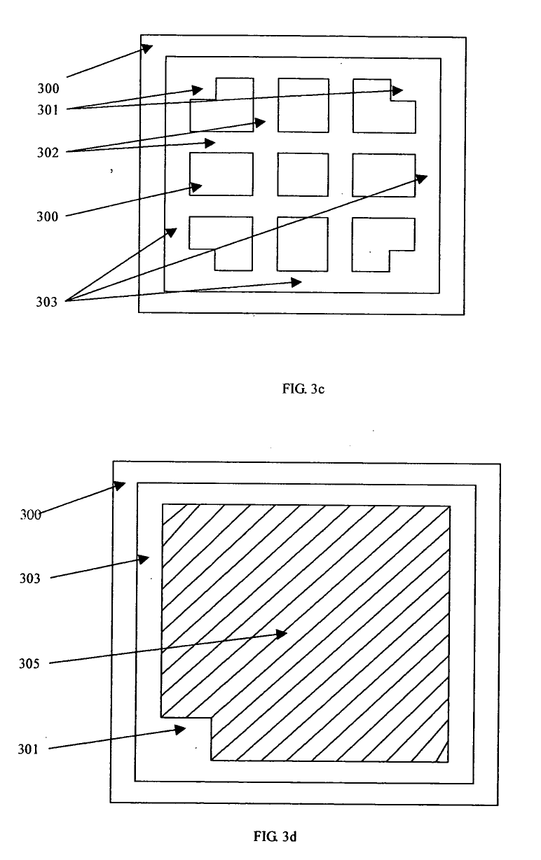

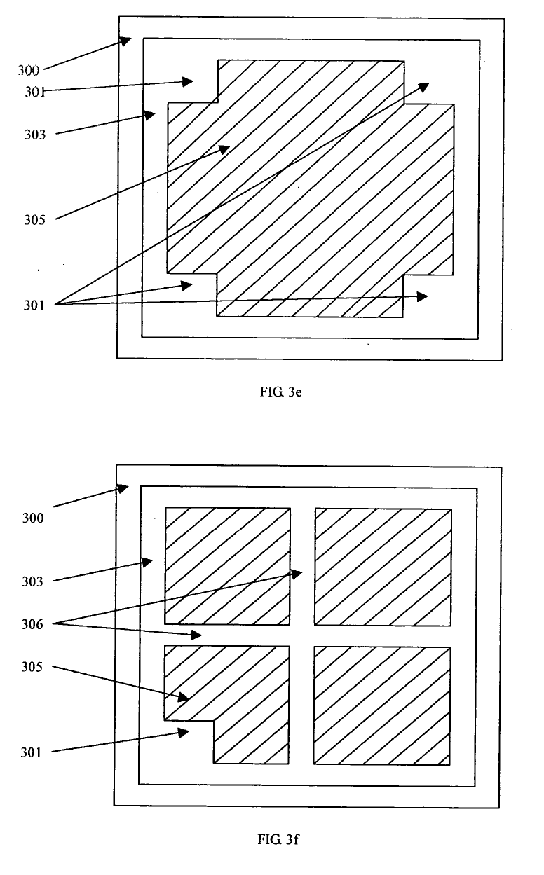

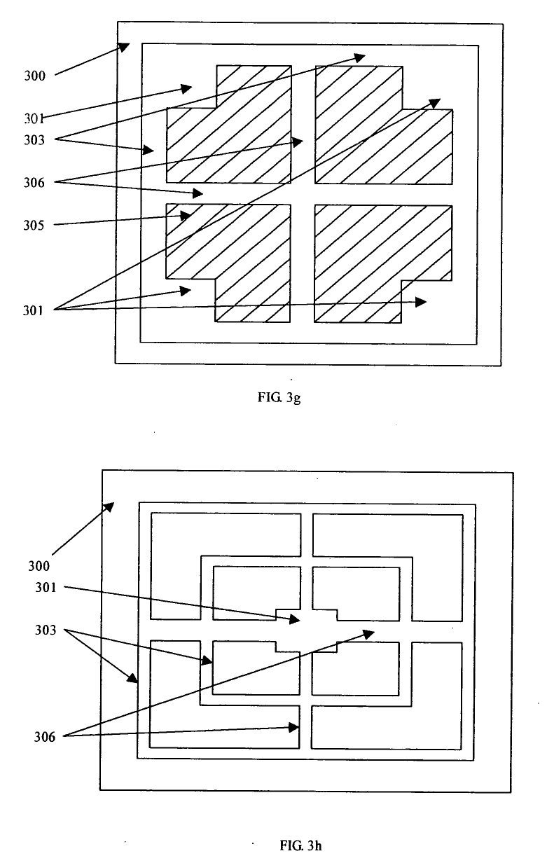

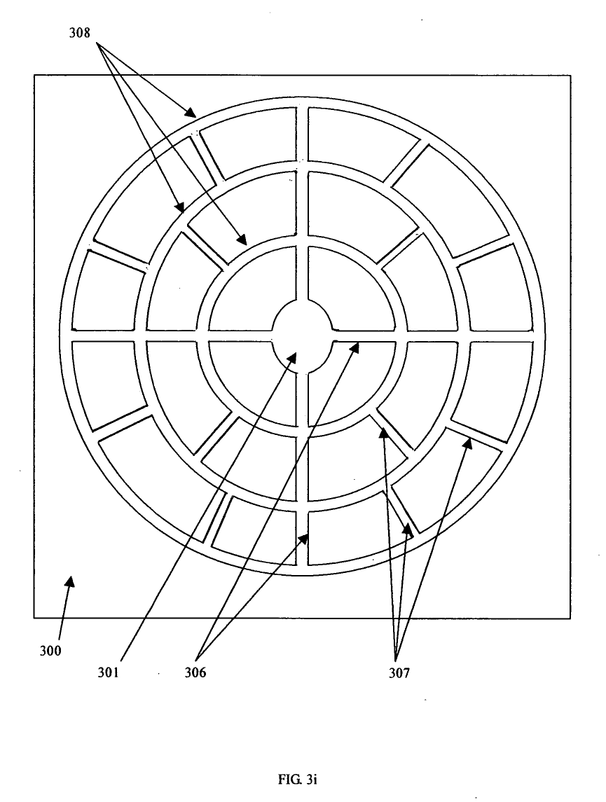

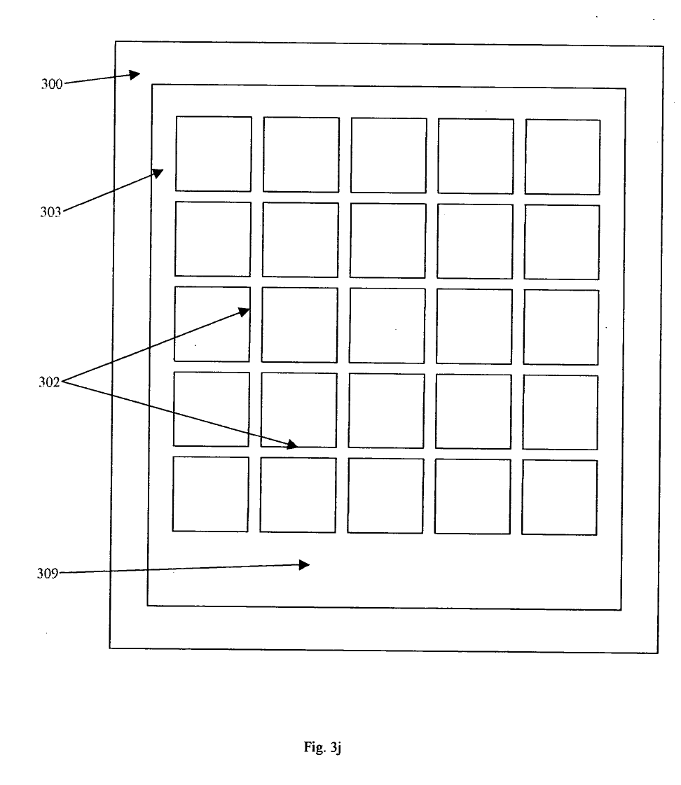

FIG. 3a to 3j present different embodiments of patterned N contact pads of the present invention.

FIG. 3a shows a grid-ring-shaped contact pad disposed on flip chip assembly 300 of a GaN LED chip. The grid-ring-shaped contact pad comprises wire bonding pad 301 at a corner of ring 303 for wire bonding. Ring 303 surrounds grid 302. The spacing between two grids is predetermined so that the current is distributed uniformly without current crowding.

FIG. 3b is a cross sectional view of flip chip assembly 300 with the grid-ring-shaped contact pad disposed on the top. The current flows from second solderable layer 205 through submount 204, first solderable layer 203, Ohmic/reflective layer 202, and epitaxial layer 201, to grid 302 and ring 303.

The current is more uniformly distributed and flows through all of active layer. Therefore the material of active layer is effectively utilized and the current density may be higher. The higher current density is proportional to higher light output power.

FIG. 3c is similar to the FIG. 3a. The dimension of a high power semiconductor chip is larger and more current flows through the chip. Plurality of wire bonding pads are needed. The pattern of FIG. 3c has 4 of wire bonding pad 301 at four corners of ring 303.

FIG. 3d shows ring-shape contact pad 303 with wire bonding pad 301 at a corner. Current spreading layer 305 covers flip chip assembly 300.

FIG. 3e is similar to FIG. 3d, but with 4 of wire bonding pad 301.

FIG. 3f shows a ring-plus-shaped contact pad comprising ring 303, plus 306, and current spreading layer 305.

FIG. 3g is similar to FIG. 3f but with 4 of wire bonding pad 301.

FIG. 3h is plus-multi-ring-shaped contact pad comprising plus 306, plurality of ring 303, and wire bonding pad 301 at the center of plus 306.

FIG. 3i shows plus-multi-ring-partition-shaped contact pad comprising plus 306, plurality of ring 308, wire bonding pad 301 at the center of plus 306, and plurality of partition 307 which are distributed between rings for distributing current uniformly.

FIG. 3j shows a grid-ring-shaped contact pad disposed on flip chip assembly 300 of a GaN LED chip. The grid-ring-shaped contact pad comprises ring 303 surrounding grid 302. The spacing between two grids is predetermined so that the current is distributed uniformly. For high power semiconductor chips, the current is high and a larger wire bonding pad is needed. Strip-shaped wire bonding pad 309 is on one side of ring 303 for either multiple wire bonding or ribbon bonding for carrying high current density.

Note that, in FIG. 3a to 3j, each of patterned contact pads may be either directly disposed on epitaxial layer or disposed on a current spreading layer which is disposed on the epitaxial layer, and each of patterned contact pads may have either one or plurality of wire bonding pads.

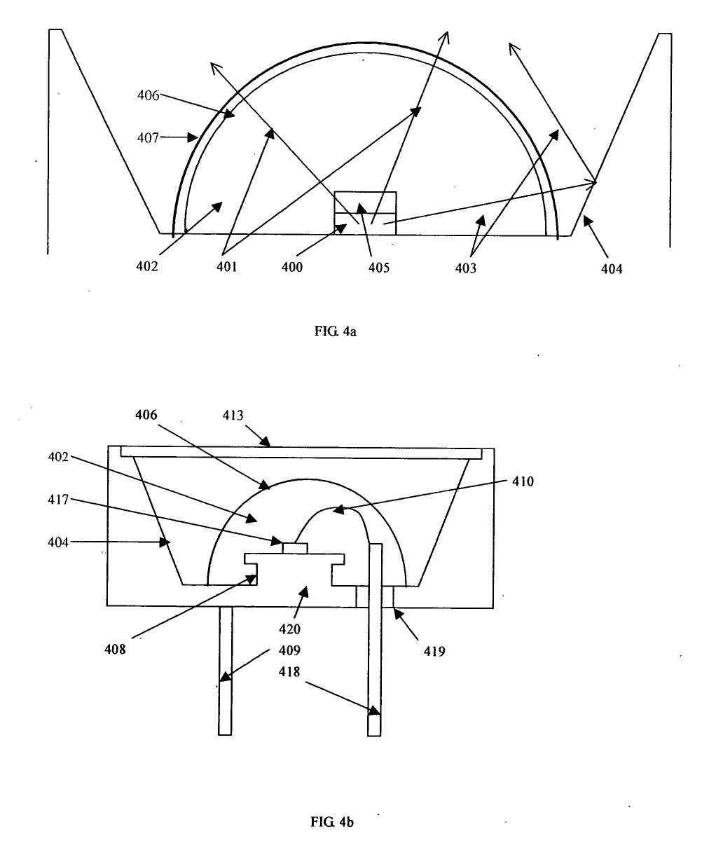

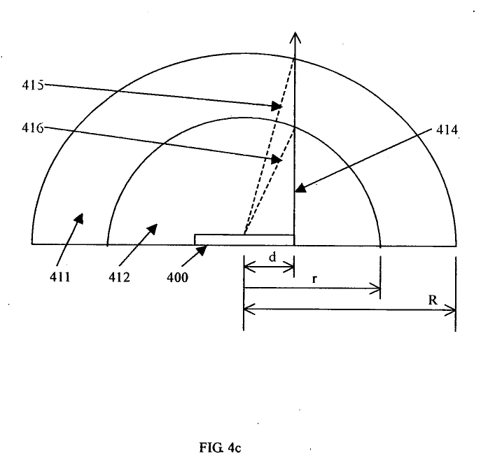

FIG. 4a shows a cross sectional view of a lamp for flip chip assemblies of semiconductor chips or devices of the present invention. The lamp comprises active layer 400 which is part of a flip chip assembly of semiconductor chips and emits light, top confinement layer 405 disposed on the top of active layer 400, transparent hemisphere-shaped material 402 which has the same refractive index as that of top confinement layer 405, and reflective cup 404. Hemisphere-shaped material 402 covers the flip chip assembly that is disposed on reflective cup 404. Anti-reflection coating 407 is disposed on surface 406 of hemisphere-shaped material 402 for reducing the Fresnel reflection.

Note that other layers of the epitaxial layer of the flip chip assembly are not shown in FIG. 4a.

One embodiment of hemisphere-shaped material 402 is made of mixing epoxy with nanometer-particle selected from a group comprising silicon or tungsten. Hemisphere-shaped material 402 guaranties that there is no totally internal reflection at the interface between top confinement layer 405 and hemisphere-shaped material 402 by having the same refractive index n as that of the epitaxial layer.

The diameter of hemisphere-shaped material 402 is determined in FIG. 4c and so that there is no totally internal reflection at the interface between hemisphere-shaped material 402 and air.

FIG. 4b shows an embodiment of lamp 420 with flip chip assembly 417 of the present invention. Lamp 420 is similar to the lamp of FIG. 4a but has neck 408 for holding hemisphere-shaped material 402, therefore, the encapsulation process is simpler. Wire 410 connects flip chip assembly 417 to lead 418 which is pass through hole 419 and isolated electrically from lamp 420. Transparent cover 413 seals flip chip assembly 417 which is covered by hemisphere-shaped material 402.

Comparing with prior art of FIG. 1b, the advantage of placing the reflective cup outside of the hemisphere-shaped material is that the emitted light is not trapt by the hemisphere-shaped material.

FIG. 4c is a schematic drawing for calculating the critical diameter of a dome. Light 414 is emitted from active layer 400 at the edge of a flip chip assembly and incidents vertically up. Hemisphere-shaped material 412 and 411 have radii r and R respectively, and r<R. The angle between light 414 and radii 416 is larger than that between light 414 and 415. When the diameter R of the hemisphere-shaped material reaching a critical size, the angle between light 414 and radii 415 is equal to or less than the Snell's critical angle, and, thus, there is no totally internal reflection.

The angle between light 414 and radii 415 is determined by half width d of the flip chip assembly and radii R. Combining with Snell's law, the following relation is obtained:
R≧nd, (a)
where n and R are the refractive index and the critical radii of hemisphere-shaped material 402, respectively, the refractive index of air is assumed to be 1. For example, a high power GaN LEDs of FIG. 4a, n=2.5. Assuming d=1 mm, the minimum radii of the hemisphere-shaped dome should be 2.5 mm for avoiding the totally internal reflection at the dome-air interface.

For the new flip chip assemblies of the present invention, due to the following facts: (1) there is no substrate, (2) refraction index of hemisphere-shaped dome material is the same as that of top confinement layer, and (3) minimum radii of hemisphere-shaped dome is determined by equation (a), there is no totally internal reflection at all, i.e., no light trapped inside the LED chip and dome material.

Although the description above contains many specifications, these should not be construed as limiting the scope of the present invention but as merely providing illustrations of some of the presently preferred embodiments of the present invention.

Therefore the scope of the present invention should be determined by the claims and their legal equivalents, rather than by the examples given.

1. A wafer level flip chip package process for manufacturing flip chip assemblies for semiconductor chips or devices, comprising the process steps of:
preparing a substrate wafer wherein said substrate wafer is precisely lapped and polished to minimize the total thickness variation;
preparing a submount wafer wherein said submount wafer is precisely lapped and polished to minimize the total thickness variation;
growing an epitaxial layer onto said substrate wafer to form an epitaxial wafer of semiconductor chips or devices; wherein said epitaxial layer comprising first confinement layer, active layer, and second confinement layer stacked on said substrate wafer; and wherein the thickness of said first confinement layer is predetermined to compensate the combination of the total thickness variations of said substrate and said submount wafers;
disposing reflective and Ohmic contact layers on said second confinement layer;
disposing a first and a second solderable layers on two sides of said submount wafer respectively, wherein the thickness of said first solderable layer is predetermined to compensate rough surface of said epitaxial layer;
pressingly bonding said reflective and Ohmic layers of said epitaxial wafer to said first solderable layer of said submount wafer to form a bonded semiconductor chip or devices wafer;
removing said substrate wafer from said bonded semiconductor chip or devices wafer so that said first confinement layer exposed;
disposing patterned contact pads on said first confinement layer, wherein each of said patterned contact pads comprising at least one wire bonding pad;
dicing said bonded semiconductor chip or device wafer into individual semiconductor chips or devices.

2. The wafer level flip chip package process of claim 1 wherein said substrate wafer is a sapphire wafer.

3. The wafer level flip chip package process of claim 2 wherein said sapphire wafer is removed by lapping and polishing process.

4. The wafer level flip chip package process of claim 1 wherein said substrate wafer is a Si wafer.

5. The wafer level flip chip package process of claim 4 wherein said Si wafer may be removed by plasma etching process.

6. The wafer level flip chip package process of claim 1 wherein said substrate wafer is a GaN wafer.

7. The wafer level flip chip package process of claim 6 wherein said GaN wafer may be removed by plasma etching process.

8. The wafer level flip chip package process of claim 1 wherein said reflective layer comprising materials selected from a group comprising Al, Au, and Ag.

9. The wafer level flip chip package process of claim 1 wherein said reflective layer is the distributed Bragg reflector.

10. The wafer level flip chip package process of claim 1 wherein the materials of said patterned contact layer are selected from a group comprising Al, Ni, Ti, and combinations thereon.

11. The wafer level flip chip package process of claim 1 wherein said submount wafer is selected from a group comprising SiC, Cu, Ag, and GaAs.

12. The wafer level flip chip package process of claim 1 wherein said first and second solderable layers is selected from a group comprising Au/Sn and Pb/Sn.

13. The wafer level flip chip package process of claim 1 further comprising a process step that a current spreading layer is sandwiched between said patterned contact pad and said first confinement layer.

14. A new flip chip assembly of semiconductor chips or devices comprising
an electrically and thermally conductive submount chip selected from materials of a group comprising SiC, Cu, Ag, and GaAs;
an epitaxial layer comprising a second confinement layer, an active layer, and a first confinement layer stacked on said submount chip;
reflective and Ohmic contact layers sandwiched between said epitaxial layer and said submount chip;
a patterned contact pad disposed on said first confinement layer wherein said patterned contact pad comprising at least one wire bonding pad.

15. The new flip chip assembly of semiconductor chips or devices of claim 14 wherein said reflective layer is a distributed Bragg reflector.

16. The new flip chip assembly of semiconductor chips or devices of claim 14 further comprising a current spreading layer sandwiched between said patterned contact pad and said first confinement layer.

17. The new flip chip assembly of semiconductor chips or devices of claim 14 wherein said patterned contact pad is a plus-ring-shaped contact pad with at least one wire bonding pad.

18. The new flip chip assembly of semiconductor chips or devices of claim 14 wherein said patterned contact pad is a grid-ring-shaped contact pad with at least one wire bonding pad.

19. The new flip chip assembly of semiconductor chips or devices of claim 14 wherein said patterned contact pad is a plus-multi-ring-shaped contact pad with at least one wire bonding pad.

20. The new flip chip assembly of semiconductor chips or devices of claim 14 wherein said patterned contact pad is a plus-multi-ring-partition-shaped contact pad with at least one wire bonding pad.

21. The new flip chip assembly of semiconductor chips or devices of claim 14 wherein said wire bonding pad being a strip-shaped wire bonding pad.

22. A new lamp for a flip chip assembly of semiconductor chips or devices comprising:
a lead frame with reflective cup;
a flip chip assembly disposed on said reflective cup and comprising an electrically and thermally conductive submount, an epitaxial layer disposed on said submount, a patterned contact pad disposed on said epitaxial layer;
a hemisphere-shape material covering said flip chip assembly and having a radii R which is equal to or larger than R=nd where d is the half of the dimension of said flip chip assembly and n is the refractive index of said hemisphere-shape material, and wherein said refractive index n is the same as that of said epitaxial layer.

23. The new lamp for a flip chip assembly of semiconductor chips or devices of claim 22 further comprising a neck portion for holding said hemisphere-shape material.

24. The new lamp for a flip chip assembly of semiconductor chips or devices of claim 22 further comprising a transparent cover.
